(19) United States
(12) Patent Application Publication
(10) Pub. No.: US 2013/0187250 A1
(43) Pub. Date: Jul. 25, 2013

(54) Semiconductor Devices Having an Enhanced Absorption Region and Associated Methods

(71) Applicant: SiOnyx, Inc., Beverly, MA (US)

(72) Inventors: James E. Carey, Waltham, MA (US); Jason Sickler, Arlington, MA (US)

(73) Assignee: SIONYX, INC., Beverly, MA (US)

(21) Appl. No.: 13/692,628

(22) Filed: Dec. 3, 2012

Related U.S. Application Data
(63) Continuation of application No. 12/910,658, filed on Oct. 22, 2010, now abandoned.
(60) Provisional application No. 61/254,107, filed on Oct. 22, 2009.

(51) Int. Cl. H01L 31/0232

(52) U.S. Cl. CPC H01L 31/02327
USPC 257/436

(57) ABSTRACT

Photosensitive semiconductor devices and associated methods are provided. In one aspect, for example, a photosensitive semiconductor device can include an electromagnetic radiation absorption layer having a thickness of less than or equal to about 200 μm, wherein the electromagnetic radiation absorption layer includes a semiconductor material and an enhanced absorption region. The electromagnetic radiation absorption layer is operable to absorb greater than or equal to about 40% of incident electromagnetic radiation having at least one wavelength greater than or equal to about 1064 nm.

### PRIORITY DATA

This application is a continuation of U.S. patent application Ser. No. 12/910,658, filed on Oct. 22, 2010, which claims the benefit of U.S. Provisional Patent Application Ser. No. 61/254,107, filed on Oct. 22, 2009, both of which are incorporated herein by reference.

### BACKGROUND

Various semiconductor devices can be used to absorb and detect photons. Such photo-detecting semiconductor devices are often affected by and provide some response to interaction with electromagnetic radiation. As one example, a photovoltaic device can include a photovoltaic cell typically formed of a silicon material. Other examples include photodiodes, photo-imagers, and the like. Silicon is an indirect band-gap material, and as such is better at absorbing than emitting various wavelengths of light. For example, silicon tends to absorb a majority of incident visible light having wavelengths in the range of about 300 nm to about 900 nm. However, because of the optical band gap of silicon (i.e. 1.05 eV or 1100 nm) many wavelengths of light pass through the material without being absorbed.

Additionally, absorption of light by silicon varies with electromagnetic radiation wavelength and with the thickness of the silicon material. Traditional silicon wafers typically have a standard wafer thickness of from about 750 to about 850 μm. At this standard wafer thickness, silicon is not able to absorb appreciable amounts of light having wavelengths greater than about 1100 nm. Silicon devices that have a thickness much less than 200 microns is not able to absorb appreciable amounts of light having wavelengths greater than about 900 nm. As a caveat, greater absorption depths have drawbacks when used in imaging devices because of increased probability of cross talk, lower image resolutions, and the increased device thickness.

### SUMMARY

The present disclosure provides photosensitive semiconductor devices and associated methods. In one aspect, for example, a photosensitive semiconductor device can include an electromagnetic radiation absorption layer having a thickness of less than or equal to about 200 μm, wherein the electromagnetic radiation absorption layer includes a semiconductor material and an enhanced absorption region. In one specific aspect, the electromagnetic radiation absorption layer is operable to absorb greater than or equal to about 40% of incident electromagnetic radiation having at least one wavelength greater than or equal to about 1060 nm.

In one aspect of the present disclosure, the electromagnetic radiation absorption layer has a thickness of less than or equal to about 20 μm. In a more specific aspect, the electromagnetic radiation absorption layer is operable to absorb greater than or equal to about 40% of incident electromagnetic radiation having at least one wavelength greater than or equal to about 940 nm. In another more specific aspect, the electromagnetic radiation absorption layer has an external quantum efficiency of at least about 40% at a wavelength of about 940 nm. In yet another specific aspect, the electromagnetic radiation absorption layer is operable to absorb greater than or equal to about 5% of incident electromagnetic radiation having at least one wavelength greater than or equal to about 1060 nm. In a further specific aspect, the electromagnetic radiation absorption layer has an external quantum efficiency of at least about 5% at a wavelength of about 1060 nm.

In another aspect of the present disclosure, the electromagnetic radiation absorption layer has a thickness of less than or equal to about 5 μm. In a more specific aspect, the electromagnetic radiation absorption layer is operable to absorb greater than or equal to about 15% of incident electromagnetic radiation having at least one wavelength greater than or equal to about 940 nm. In another specific aspect, the electromagnetic radiation absorption layer has an external quantum efficiency of at least about 15% at a wavelength of about 940 nm. In yet another specific aspect, the electromagnetic radiation absorption layer is operable to absorb greater than or equal to about 2% of incident electromagnetic radiation having at least one wavelength greater than or equal to about 1060 nm. In a further specific aspect, the electromagnetic radiation absorption layer has an external quantum efficiency of at least about 2% at a wavelength of about 1060 nm.

A variety of semiconductor materials are contemplated for use in aspects of the present disclosure. Nonlimiting examples of such materials can include group IV materials, compounds and alloys comprising materials from groups II and VI, compounds and alloys comprising materials from groups III and V, and combinations thereof. In one specific aspect, the semiconductor material is silicon.

The electromagnetic radiation layer can have a variety of configurations and properties, depending on the desired use. In one aspect, for example, the electromagnetic radiation absorption layer has a thickness of from about 500 nm to about 100 μm. In another aspect, the electromagnetic radiation absorption layer has a thickness of from about 500 nm to about 15 μm. In yet another aspect, the electromagnetic radiation absorption layer has a thickness of from about 500 nm to about 5 μm. In a further aspect, the electromagnetic radiation absorption layer has an external quantum efficiency of at least about 40% at a wavelength of about 1060 nm. In some aspects, the electromagnetic radiation absorption layer can have a low oxygen content. In one specific aspect, the electromagnetic radiation absorption layer has an oxygen content of less than about 50 ppma.

The enhanced absorption region can be made by a number of processes, all of which should be considered to be within the present scope. In one aspect, however, the enhanced absorption region is a laser enhanced absorption region. Such a laser enhanced absorption region can, in some aspects, include surface features having heights that are micron-sized, nano-sized, and combinations thereof. In one specific aspect, the surface features have a height of from about 50 nm to about 2 μm. Surface features also can be produced in a variety of configurations. Nonlimiting examples of surface features include cones, pillars, pyramids, microlenses, spheres-like structures, quantum dots, inverted features, and the like, including combinations thereof. In some aspects, the laser enhanced absorption region is doped, and in one aspect the laser enhanced absorption region includes a substantially conformal textured layer having a thickness of from about 1 nm to about 20 μm.

In another aspect of the present disclosure, a method of making a photosensitive semiconductor device is provided. Such a method can include laser processing a region of a semiconductor material to form a laser enhanced absorption region, where the laser enhanced absorption region and the semiconductor material form an electromagnetic radiation absorption layer having a thickness of less than or equal to about 200 μm. Additionally, the electromagnetic radiation absorption layer is operable to absorb greater than or equal to about 40% of incident electromagnetic radiation having at least one wavelength greater than or equal to about 1064 nm.

In one aspect, the method can also include annealing the electromagnetic radiation absorption layer to a temperature of from about 300° C. to about 1100° C. Additionally, in some aspects the semiconductor material has a low oxygen content and the laser processing and the annealing are performed in a substantially oxygen-depleted environment. In other aspects, laser processing the region includes exposing laser radiation to a dopant such that the laser processing incorporates the dopant into the laser enhanced absorption region.

In another aspect of the present disclosure, a photosensitive semiconductor device is provided comprising an electromagnetic radiation absorption layer having a thickness of X including a semiconductor material and an enhanced absorption region. The electromagnetic radiation absorption layer has an enhanced absorptance of electromagnetic radiation having a wavelength of about Y that is greater than or equal to about 105% of the absorptance of electromagnetic radiation having a wavelength of about Y by an absorption layer of the same semiconductor material of thickness X and lacking the enhanced absorption region. In one specific aspect, the semiconductor material is silicon. In one aspect, X is from about 500 nm to about 850 μm. In another aspect, Y is from about 360 nm to about 2000 nm.

In another aspect of the present disclosure, a photosensitive silicon device can include an electromagnetic radiation absorption layer having a thickness of less than or equal to about 5 μm, wherein the electromagnetic radiation absorption layer includes a silicon material and an enhanced absorption region, and wherein the electromagnetic radiation absorption layer has an external quantum efficiency of greater than or equal to about 15% of incident electromagnetic radiation having at least one wavelength greater than or equal to about 940 nm.

### BRIEF DESCRIPTION OF THE DRAWINGS

FIG. 1 is a schematic view of a photosensitive semiconductor device in accordance with one aspect of the present disclosure;

FIG. 2 is a schematic view of a photosensitive semiconductor device in accordance with another aspect of the present disclosure;

FIG. 3 is a schematic view of a photosensitive semiconductor device in accordance with yet another aspect of the present disclosure;

FIG. 4 is a schematic view of a photosensitive semiconductor device in accordance with a further aspect of the present disclosure; and

FIG. 5 is a depiction of a method of making a photosensitive semiconductor device in accordance with yet another aspect of the present disclosure.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

### DEFINITIONS

The following terminology will be used in accordance with the definitions set forth below.

It should be noted that, as used in this specification and the appended claims, the singular forms “a,” and, “the” include plural referents unless the context clearly dictates otherwise. Thus, for example, reference to “a dopant” includes one or more of such dopants and reference to “the layer” includes reference to one or more of such layers.

As used herein, the term “low oxygen content” refers to any material having an interstitial oxygen content that is less than or equal to about 60 ppm atomic.

As used herein, the terms “disordered surface” and “textured surface” can be used interchangeably, and refer to a surface having a topology with nano- to micron-sized surface variations formed by the irradiation of laser pulses. While the characteristics of such a surface can be variable depending on the materials and techniques employed, in one aspect such a surface can be several hundred nanometers thick and made up of nanocrystallites (e.g. from about 10 to about 50 nanometers) and nanopores. In another aspect, such a surface can include micron-sized structures (e.g. about 2 μm to about 60 μm). In yet another aspect, the surface can include nano-sized and/or micron-sized structures from about 5 nm and about 500 μm.

As used herein, the term “absorptance” refers to the fraction of incident electromagnetic radiation absorbed by a material or device.

As used herein, the term “fluence” refers to the amount of energy from a single pulse of laser radiation that passes through a unit area. In other words, “fluence” can be described as the energy density of one laser pulse.

As used herein, the terms “surface modifying” and “surface modification” refer to the altering of a surface of a semiconductor material using laser radiation. In one specific aspect, surface modification can include processes using primarily laser radiation or laser radiation in combination with a dopant, whereby the laser radiation facilitates the incorporation of the dopant into a surface of the semiconductor material. Accordingly, in one aspect surface modification includes doping of a semiconductor material.

As used herein, the term “target region” refers to an area of a semiconductor material that is intended to be doped or surface modified using laser radiation. The target region of a semiconductor material can vary as the surface modifying process progresses. For example, after a first target region is doped or surface modified, a second target region may be selected on the same semiconductor material.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

The Disclosure

The present disclosure is drawn to semiconductor devices having an absorbing layer including an enhanced absorption region that increases the amount of electromagnetic radiation that is absorbed. Although not required, in some aspects the devices disclosed herein can be made using thinner semiconductor materials to detect and absorb electromagnetic radiation at higher wavelengths (e.g. >1000 nm). Thus, enhanced external quantum efficiency and absorption of electromagnetic radiation can have a positive impact for many electromagnetic radiation absorbing applications such as, for example, photodiodes, photo imagers, photovoltaic devices, and the like.

Electromagnetic radiation can be present across a broad wavelength range, including visible range wavelengths (approximately 350 nm to 800 nm) and non-visible wavelengths (longer than about 800 nm or shorter than 350 nm). The infrared spectrum is often described as including a near infrared portion of the spectrum including wavelengths of approximately 800 to 1300 nm, a short wave infrared portion of the spectrum including wavelengths of approximately 1300 nm to 3 μm, and a mid to long wave infrared (or thermal infrared) portion of the spectrum including wavelengths greater than about 3 μm up to about 30 μm. These are generally and collectively referred to herein as “infrared” portions of the electromagnetic spectrum unless otherwise noted.

Traditional silicon photosensitive devices have limited light absorption/detection properties. For example, these silicon based detectors are mostly transparent to infrared light. Traditional silicon materials require substantial thicknesses to detect photons having wavelengths longer than approximately 900 nm. The devices of the present disclosure function to increase the absorption of semiconductor materials, including silicon, by decreasing the effective absorption length for longer wavelengths as compared to traditional materials. For example, the absorption depth of silicon can be reduced such that these longer wavelengths can be absorbed at depths of less than or equal to about 850 μm. By decreasing the effective absorption length these devices are able to absorb longer wavelengths (e.g. >1000 nm for silicon) within a thin semiconductor material. In addition to increasing the effective absorption length, the response rate or response speed can also be increased by using thinner semiconductor materials.

The effective reflection and transmission properties of the interfaces of an absorption layer can impact the total absorptance of that layer. For example, an anti-reflective layer disposed on a side of an absorption layer (i.e. an electromagnetic radiation absorption layer) where electromagnetic radiation is incident can improve the electromagnetic radiation transmitted into the layer, and hence will lead to improved absorptance over the case where an anti-reflective layer is absent. As such, it should be noted that statements of improvements (e.g. improved absorption) herein are intended to be with respect to comparisons between devices that have suitably similar effective reflection and transmission properties at the layer interfaces at the wavelengths of interest.

Additionally, with some combinations of effective reflection and transmission properties and physical dimensions of an absorbing layer, resonant behavior can be achieved throughout the entire absorbing layer. This effect depends on the wave interference of the electromagnetic radiation throughout the entire layer, and results in enhanced absorptance over a range of wavelengths, essentially by causing photons to repeatedly propagate throughout the layer. One characteristic of resonant behavior is that the magnitude of enhancement and the range of wavelengths over which it operates are inversely proportionally. That is, the greater an enhancement it creates, the narrower the range of wavelengths that are enhanced. While resonant behavior can be used to provide a level of enhancement, the devices and methods described herein display absorptance enhancements that are generally broadband, in some cases enhancing an optical bandwidth of about 1% or more. Additionally, the absorptance enhancement of the present disclosure depends little on the constructive interference of the incident light throughout the entire layer, and thus is substantially not the result of resonant absorptance enhancement resulting from the layer interface reflection and transmission properties.

Additionally, the absorption properties of a semiconductor material such as silicon are dependent on temperature. Altering the temperature of the semiconductor material can affect the amount of incident radiation absorbed, as well as the wavelengths of the radiation absorbed. For example, increasing the temperature on a non-enhanced silicon substrate to greater than 400 K can allow the substrate to absorb electromagnetic radiation having a wavelength in the near infrared region. It should be understood, therefore, that the various numerical values described herein are with respect to semiconductor materials at a temperature in the range of from about 233 K to about 373 K, unless otherwise noted.

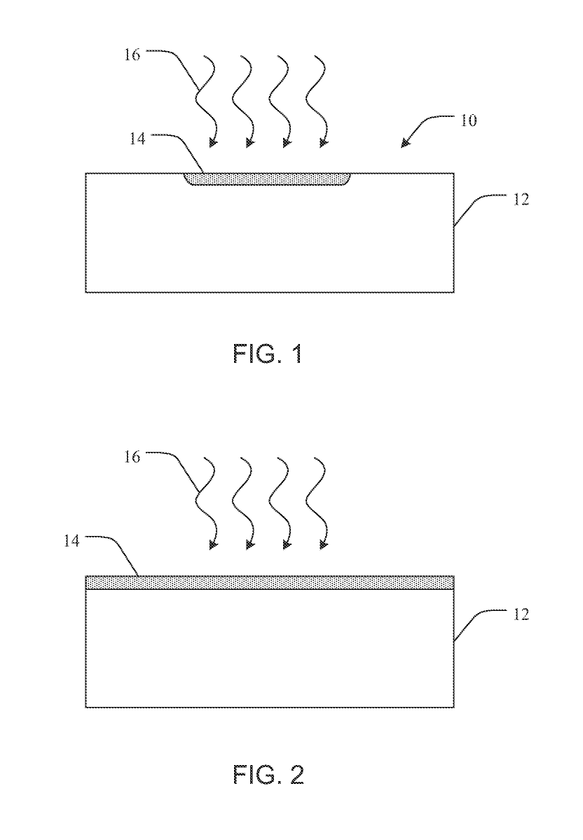

Accordingly, aspects of the present disclosure utilize an electromagnetic radiation absorption layer comprised of a semiconductor material and an enhanced absorption region that facilitates enhanced absorptance of electromagnetic radiation impinging thereon as compared to traditional materials. In one aspect, as is shown in FIG. 1, a photosensitive semiconductor device is provided. It is noted that this FIG., as well as the other FIGS., are shown schematically, and thus, are not necessarily drawn to scale. Such a device can include an electromagnetic radiation absorption layer 10 having a thickness of less than or equal to about 200 μm. The electromagnetic radiation absorption layer includes a semiconductor material 12 and an enhanced absorption region 14. In one aspect, the electromagnetic radiation absorption layer is operable to absorb greater than or equal to about 40% of incident electromagnetic radiation 16 having at least one wavelength greater than or equal to about 1064 nm. In another aspect, the electromagnetic radiation absorption layer has a thickness of less than or equal to about 20 μm. In yet another aspect, the electromagnetic radiation absorption layer has a thickness of less than or equal to about 20 μm and is operable to absorb greater than or equal to about 40% of incident electromagnetic radiation having at least one wavelength greater than or equal to about 940 nm. In a further aspect, the electromagnetic radiation absorption layer has a thickness of less than or equal to about 20 μm and has an external quantum efficiency of at least about 40% at a wavelength of about 940 nm. In yet a further aspect, the electromagnetic radiation absorption layer has a thickness of less than or equal to about 20 μm and is operable to absorb greater than or equal to about 5% of incident electromagnetic radiation having at least one wavelength greater than or equal to about 1060 nm. In yet another aspect, the electromagnetic radiation absorption layer has a thickness of less than or equal to about 20 μm and has an external quantum efficiency of at least about 5% at a wavelength of about 1060 nm.

In one aspect, the electromagnetic radiation absorption layer has a thickness of less than or equal to about 5 μm. In another aspect, the electromagnetic radiation absorption layer has a thickness of less than or equal to about 5 μm and is operable to absorb greater than or equal to about 15% of incident electromagnetic radiation having at least one wavelength greater than or equal to about 940 nm. In yet another aspect, the electromagnetic radiation absorption layer has a thickness of less than or equal to about 5 μm and has an external quantum efficiency of at least about 15% at a wavelength of about 940 nm. In a further aspect, the electromagnetic radiation absorption layer has a thickness of less than or equal to about 5 μm and is operable to absorb greater than or equal to about 2% of incident electromagnetic radiation having at least one wavelength greater than or equal to about 1060 nm. In yet a further aspect, the electromagnetic radiation absorption layer has a thickness of less than or equal to about 5 μm and has an external quantum efficiency of at least about 2% at a wavelength of about 1060 nm.

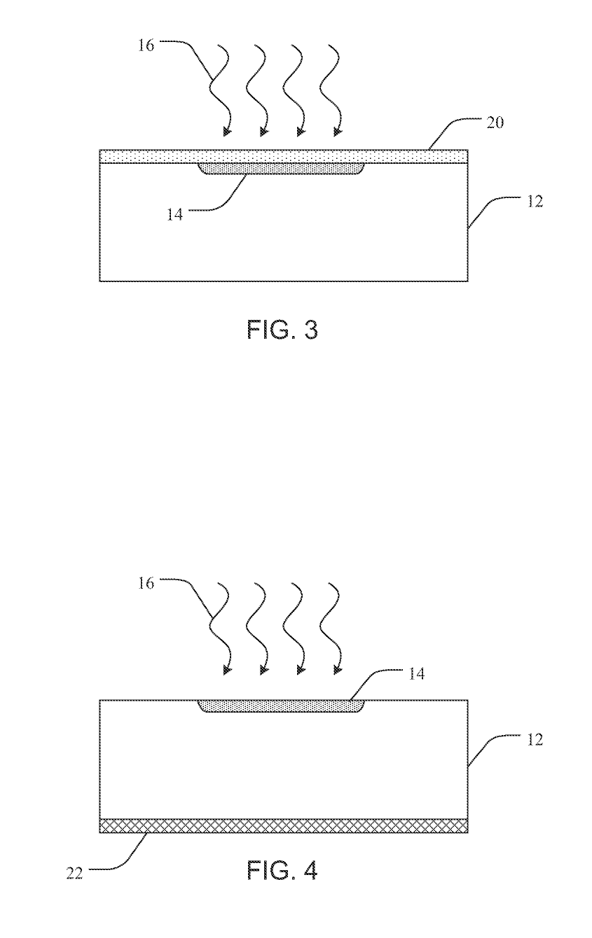

In one aspect the enhanced absorption region can be disposed on only a portion of one side of the semiconductor material as is shown in FIG. 1. In another aspect, as is shown in FIG. 2, the enhanced absorption region 14 can be disposed across and entire surface or across substantially the entire surface of the semiconductor material 12 as is shown in FIG. 2. In another aspect, the enhanced absorption region can be located on a side of the semiconductor material that is opposite the incident electromagnetic radiation (not shown). Additionally, electrical contacts are not shown in FIGS. 1-4 for clarity; however, they can be positioned as desired or convenient, as would be apparent to one skilled in the art after considering the present disclosure.

In many aspects, transmission and reflection coefficients at interfaces of the electromagnetic radiation absorption layer can affect absorptance of the device. FIG. 3, for example, shows a semiconductor material 12 and an enhanced absorption region 14. An anti-reflective layer 20 is shown disposed on the device to increase transmittance of electromagnetic radiation 16 into the device. It is noted that the enhanced absorption region 14 can be located adjacent to the anti-reflective layer as is shown in FIG. 3, or opposite to the anti-reflective layer (not shown).

In another aspect, as is shown in FIG. 4, a reflective layer 22 is disposed on the semiconductor material 12 on a side opposite to the incident electromagnetic radiation 16. The reflective layer functions to increase the reflection of electromagnetic radiation back through the semiconductor material. It is noted that the enhanced absorption region 14 can be located opposite to the reflective layer as is shown in FIG. 4, or adjacent to the reflective layer (not shown). In some aspects, the enhanced absorption region can also be buried within the semiconductor material. One example of such a configuration may include, without limitation, a wafer-bonded configuration.

Various aspects utilizing combinations of transmission and reflection coefficients are contemplated, and any such combination is considered to be within the present scope. For example, in one aspect, the electromagnetic radiation absorption layer can be uncoated on either side, or, in other words, can lack both an anti-reflective layer on the front and a reflective layer on the back.

In another aspect, the electromagnetic radiation absorption layer can have about a 10% reflection on the front and about a 100% reflection on the back. One example is a device having a low-reflectivity surface texture on the front and a high-reflectivity layer such as a mirror on the back. One specific example of such a device would be a textured photovoltaic cell.

In yet another aspect, the electromagnetic radiation absorption layer can have about a 2% reflection on the front and about a 100% reflection on the back. One example is a device having an anti-reflective coating on the front and a high-reflectivity layer such as a mirror on the back. Specific examples of such a device would be a photovoltaic cell with nitride and a back metal, or a photodiode or imager device that is thinned and has a back mirror.

In a further aspect, the electromagnetic radiation absorption layer can have about a 2% reflection on the front and about a 17.5% reflection on the back. One example is a device having an anti-reflective coating on the front and a dielectric material on the back. A specific example may include a device such as a silicon on insulator (SOI) imager or photodetector.

In yet a further aspect, the electromagnetic radiation absorption layer can have about a 2% reflection on the front and about a 7% reflection on the back. One example is a device having an anti-reflective coating on the front and a dielectric material on the back. A specific example may include a device such as an imager or photovoltaic device with silicon on thick silicon nitride.

In another aspect, the electromagnetic radiation absorption layer can have about a 2% reflection on the front and about a 0% reflection on the back. One example is a device having an anti-reflective coating on the front and a refractive index-matched material causing no reflection on the back. One specific example may include an epitaxial wafer device.

The present photosensitive devices exhibit enhanced absorption compared to traditional materials. In one aspect, for example, a photosensitive semiconductor device is provided including an electromagnetic radiation absorption layer having a thickness of X including a semiconductor material and an enhanced absorption region, wherein the electromagnetic radiation absorption layer has an enhanced absorptance of electromagnetic radiation having a wavelength of Y that is greater than or equal to about 105% of the absorptance of electromagnetic radiation having a wavelength of Y by an absorption layer of the same semiconductor material of thickness X and lacking the enhanced absorption region. Thus, an electromagnetic radiation absorption layer having a given thickness X has an enhanced absorption for electromagnetic radiation of a given wavelength Y that is greater than or equal to about 105% compared to the absorptance at the same wavelength Y of a semiconductor material of the same thickness X that does not contain the enhanced absorption region. In one aspect, the semiconductor material is silicon. In one aspect, X is from about 500 nm to about 850 μm. In another aspect, Y is from about 360 nm to about 2000 nm. In yet another specific, Y is greater than or equal to about 360 nm. In a further aspect, Y is greater than or equal to about 700 nm.

The electromagnetic radiation absorbing layers according to aspects of the present disclosure described as having a thickness of about d, and operating at a wavelength of about λ, wherein the electromagnetic radiation absorption layer includes a semiconductor material and an enhanced absorption region. The electromagnetic radiation absorption layer has a total absorptance of A(λ) that is equal to or greater than about 105% of the absorptance, A₀(λ), of an identical layer that lacks the enhanced absorption region. In this way, the enhanced absorptance is described in terms of the absorptance of the known properties of the semiconductor material contained in the absorbing layer, and whose absorption coefficient is α(λ). Note that the dependence of parameters on wavelength is explicitly indicated.

The meaning of the absorption coefficient, α(λ), is captured by the Beer-Lambert equation, as is shown in Equation (I):

T(λ)=exp[−∝(λ)d] (1)

where T(λ) is the fraction of transmitted electromagnetic radiation power.

The absorptance of the semiconductor material at wavelength λ can be calculated using the known semiconductor material's absorption coefficient α(λ), the layer thickness d, and the front and back layer interface power reflection coefficients, R_{F}(λ) and R_{B}(λ), respectively. The front and back layer interfaces are defined as those that are closest to and farthest from the incident light source during operation, respectively. Using these values, the absorptance that the semiconductor material that lacks the enhanced absorption region will demonstrate can be calculated using Equation (II):

$${A}_{0} ( λ ) = \frac{\begin{matrix}( 1 - {R}_{F} ( λ ) ) ( 1 - exp ( - α ( λ ) d ) ) \\ ( 1 + {R}_{B} ( λ ) exp ( - α ( λ ) d ) )\end{matrix}}{1 - {R}_{B} ( λ ) {R}_{F} ( λ ) exp ( - 2 α ( λ ) d )} \qquad ( II )$$

One skilled in the art would understand that the interface reflection coefficients will depend on the device design, and, once in possession of the present disclosure, will be able to calculate and/or measure these power reflection coefficients.

As is shown by Equation (III), in one aspect devices of the present disclosure will demonstrate absorptance equal to or greater than about:

A(λ)=1.05A₀(λ) (III)

In cases where the known semiconductor absorptance is substantially zero (e.g. at wavelengths greater than or equal to 1200 nm), absorptance values of equal to or greater than about 0.01% can be achieved with the inclusion of the enhanced absorption region.

In one aspect, for example, a photosensitive semiconductor device comprises an electromagnetic radiation absorption layer having a thickness of less than or equal to about 200 microns, wherein the electromagnetic radiation absorption layer includes a semiconductor material and a laser enhanced absorption region, and wherein the electromagnetic radiation absorption layer is operable to absorb with an effective absorption coefficient of greater than or equal to about 11.59 cm⁻¹ having at least one wavelength greater than or equal to about 1064 nm.

In another aspect, a photosensitive semiconductor device comprises an electromagnetic radiation absorption layer having a thickness of less than or equal to about 200 microns, wherein the electromagnetic radiation absorption layer includes a semiconductor material and a laser enhanced absorption region, and wherein the electromagnetic radiation absorption layer is operable to absorb with an effective absorption coefficient of greater than or equal to about 129.7 cm⁻¹ having at least one wavelength greater than or equal to about 940 nm.

In yet another aspect, a photosensitive semiconductor device comprises an electromagnetic radiation absorption layer having a thickness of less than or equal to about 200 microns, wherein the electromagnetic radiation absorption layer includes a semiconductor material and a laser enhanced absorption region, and wherein the electromagnetic radiation absorption layer is operable to absorb with an effective absorption coefficient of greater than or equal to about 0.65 cm⁻¹ having at least one wavelength greater than or equal to about 1215 nm.

In a further aspect, a photosensitive semiconductor device comprises an electromagnetic radiation absorption layer having a thickness of less than or equal to about 200 microns, wherein the electromagnetic radiation absorption layer includes a semiconductor material and a laser enhanced absorption region, and wherein the electromagnetic radiation absorption layer is operable to absorb with an effective absorption coefficient of greater than or equal to about 0.51 cm⁻¹ having at least one wavelength greater than or equal to about 1280 nm.

In yet a further aspect, a photosensitive semiconductor device comprises an electromagnetic radiation absorption layer having a thickness of less than or equal to about 200 microns, wherein the electromagnetic radiation absorption layer includes a semiconductor material and a laser enhanced absorption region, and wherein the electromagnetic radiation absorption layer is operable to absorb with an effective absorption coefficient of greater than or equal to about 0.268 cm⁻¹ having at least one wavelength greater than or equal to about 1480 nm.

In another aspect, the electromagnetic radiation absorption layer has a thickness of less than or equal to about 5 μm and is operable to absorb greater than or equal to about 0.566% of incident electromagnetic radiation having at least one wavelength greater than or equal to about 1064 nm.

In yet another aspect, the electromagnetic radiation absorption layer has a thickness of less than or equal to about 5 μm and is operable to absorb greater than or equal to about 6.161% of incident electromagnetic radiation having at least one wavelength greater than or equal to about 940 nm.

Tables 1-6 provide examples of absorptance values for enhanced electromagnetic radiation absorption layers where the semiconductor material is silicon. These tables describe electromagnetic radiation absorption layers having a light power effective reflection coefficient of about K % at the interface facing towards the incident electromagnetic radiation, a light power effective reflection coefficient of about L % at the interface facing away from the incident light, and having a thickness of less than or equal to about X μm. The electromagnetic radiation absorption layer includes a silicon material and a laser enhanced absorption region, wherein the electromagnetic radiation absorption layer is operable to absorb greater than or equal to about Y % of incident electromagnetic radiation having at least one wavelength greater than or equal to about Z nm.

In cases where the semiconductor layer is comprised of primarily silicon atoms, specific embodiments in this set include the following pairs of values:

TABLE 1
K = 31%, L = 31%

| Wavelength, Z (nm) | Thickness, X (μm) | Absorptance, Y (%) |
|---|---|---|
| 940 | 5 | 6.2% |
| 1064 | 1 | 0.12% |
| 1064 | 5 | 0.58% |
| 1064 | 20 | 2.3% |
| 1064 | 100 | 11% |
| 1064 | 200 | 20% |
| 1215 | 5 | 0.033% |
| 1280 | 5 | 0.026% |
| 1480 | 5 | 0.013% |

TABLE 2
K = 10%, L = 100%

| Wavelength, Z (nm) | Thickness, X (μm) | Absorptance, Y (%) |
|---|---|---|
| 940 | 5 | 12% |
| 1064 | 1 | 0.23% |
| 1064 | 5 | 1.2% |
| 1064 | 20 | 4.5% |
| 1064 | 100 | 20% |
| 1064 | 200 | 36% |
| 1215 | 5 | 0.033% |
| 1280 | 5 | 0.026% |
| 1480 | 5 | 0.013% |

TABLE 3
K = 2%, L = 100%

| Wavelength, Z (nm) | Thickness, X (μm) | Absorptance, Y (%) |
|---|---|---|
| 940 | 5 | 12% |
| 1064 | 1 | 0.23% |
| 1064 | 5 | 1.2% |
| 1064 | 20 | 4.5% |
| 1064 | 100 | 21% |
| 1064 | 200 | 37% |
| 1215 | 5 | 0.033% |
| 1280 | 5 | 0.026% |
| 1480 | 5 | 0.013% |

TABLE 4
K = 2%, L = 17.5%

| Wavelength, Z (nm) | Thickness, X (μm) | Absorptance, Y (%) |
|---|---|---|
| 940 | 5 | 7.2% |
| 1064 | 1 | 0.13% |
| 1064 | 5 | 0.67% |
| 1064 | 20 | 2.6% |
| 1064 | 100 | 12% |
| 1064 | 200 | 23% |
| 1215 | 5 | 0.033% |
| 1280 | 5 | 0.026% |
| 1480 | 5 | 0.013% |

TABLE 5
K = 2%, L = 7%

| Wavelength, Z (nm) | Thickness, X (μm) | Absorptance, Y (%) |
|---|---|---|
| 940 | 5 | 6.6% |
| 1064 | 1 | 0.12% |
| 1064 | 5 | 0.61% |
| 1064 | 20 | 2.4% |
| 1064 | 100 | 11 |
| 1064 | 200 | 22% |
| 1215 | 5 | 0.033% |
| 1280 | 5 | 0.026% |
| 1480 | 5 | 0.013% |

TABLE 6
K = 2%, L = 0%

| Wavelength, Z (nm) | Thickness, X (μm) | Absorptance, Y (%) |
|---|---|---|
| 940 | 5 | 6.2% |
| 1064 | 1 | 0.11% |
| 1064 | 5 | 0.57% |
| 1064 | 20 | 2.2% |
| 1064 | 100 | 11% |
| 1064 | 200 | 20% |
| 1215 | 5 | 0.033% |
| 1280 | 5 | 0.026% |
| 1480 | 5 | 0.013% |

In another aspect of the present disclosure, an electromagnetic radiation absorption layer can be described in terms of External Quantum Efficiency (EQE). EQE can be defined according to Equation (IV):

EQE=Nₑ/Nᵥ (IV)

where Nₑ is the number of electron-hole pairs collected, and Nᵥ is the number of photons incident on the device. In some cases, the EQE is measured at a zero applied bias to the device.

In one aspect, a silicon electromagnetic radiation absorption layer having a thickness of less than or equal to about 200 μm has an EQE of at least about 40% at a wavelength of about 1064 nm. In another aspect, a silicon electromagnetic radiation absorption layer having a thickness of less than or equal to about 20 μm has an EQE of at least about 40% at a wavelength of about 940 nm. In yet another aspect, a silicon electromagnetic radiation absorption layer having a thickness of less than or equal to about 5 μm has an EQE of at least about 15% at a wavelength of greater than about 940 nm. In yet another aspect, a silicon electromagnetic radiation absorption layer having a thickness of less than or equal to about 5 μm has an EQE of at least about 15% at a wavelength of greater than about 1000 nm.

In one specific aspect, a photosensitive silicon device can include an electromagnetic radiation absorption layer having a thickness of less than or equal to about 5 μm, wherein the electromagnetic radiation absorption layer includes a silicon material and an enhanced absorption region. The electromagnetic radiation absorption layer has an EQE of greater than or equal to about 15% of incident electromagnetic radiation having at least one wavelength greater than or equal to about 940 nm. In another aspect, EQE can be greater than or equal to about 2% for at least one wavelength greater than or equal to 1060 nm.

A variety of semiconductor materials are contemplated for use with the devices and methods according to aspects of the present disclosure. Non-limiting examples of such semiconductor materials can include group IV materials, compounds and alloys comprised of materials from groups II and VI, compounds and alloys comprised of materials from groups III and V, and combinations thereof. More specifically, exemplary group IV materials can include silicon, carbon (e.g. diamond), germanium, and combinations thereof. Various exemplary combinations of group IV materials can include silicon carbide (SiC) and silicon germanium (SiGe). In one specific aspect, the semiconductor material can be or include silicon. Exemplary silicon materials can include amorphous silicon (a-Si), microcrystalline silicon, multicrystalline silicon, and monocrystalline silicon, as well as other crystal types. In another aspect, the semiconductor material can include at least one of silicon, carbon, germanium, aluminum nitride, gallium nitride, indium gallium arsenide, aluminum gallium arsenide, and combinations thereof.

Exemplary combinations of group II-VI materials can include cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe, CZT), mercury cadmium telluride (HgCdTe), mercury zinc telluride (HgZnTe), mercury zinc selenide (HgZnSe), and combinations thereof.

Exemplary combinations of group III-V materials can include aluminum antimonide (AlSb), aluminum arsenide (AlAs), aluminum nitride (AlN), aluminum phosphide (AlP), boron nitride (BN), boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP), aluminum gallium arsenide (AlGaAs, AlₓGa₁₋ₓAs), indium gallium arsenide (InGaAs, InₓGa₁₋ₓAs), indium gallium phosphide (InGaP), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), aluminum indium arsenide phosphide (AIInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide antimonide (GaInNAsSb), gallium indium arsenide antimonide phosphide (GaInAsSbP), and combinations thereof.

The semiconductor material can be of any thickness that allows electromagnetic radiation absorption functionality according to aspects of the present disclosure, and thus any such thickness of semiconductor material is considered to be within the present scope. The enhanced absorption region can increase the efficiency of the device such that, in some aspects, the semiconductor material can be thinner than has previously been possible. Decreasing the thickness reduces the amount of semiconductor material required to make such a device. In one aspect, for example, the semiconductor material has a thickness of from about 500 nm to about 50 μm. In another aspect, the semiconductor material has a thickness of less than or equal to about 500 μm. In yet another aspect, the semiconductor material has a thickness of from about 1 μm to about 10 μm. In a further aspect, the semiconductor material can have a thickness of from about 5 μm to about 750 μm. In yet a further aspect, the semiconductor material can have a thickness of from about 5 μm to about 100 μm.

Additionally, various types of semiconductor materials are contemplated, and any such material that can be incorporated into an electromagnetic radiation absorption layer is considered to be within the present scope. In one aspect, for example, the semiconductor material is monocrystalline. In another aspect, the semiconductor material is multicrystalline. In yet another aspect, the semiconductor material is microcrystalline. It is also contemplated that the semiconductor material can be amorphous.

Furthermore, the semiconductor material according to aspects of the present disclosure can comprise multiple layers. In some aspects, layers can vary in majority carrier polarity (i.e. donor or acceptor impurities). The donor or acceptor impurities are typically determined by the type of dopant/impurities introduced into the device either through a growth process, deposition process, epitaxial process, implant process, lasing process or other known process to those skilled in the art. In some aspects such semiconductor materials can include an n-type layer, an intrinsic (i-type) layer, and a p-type layer, thus forming a p-i-n semiconductor material stack that creates a junction and/or depletion region. A semiconductor material devoid of an i-type layer is also contemplated in accordance with the present disclosure. In other aspects the semiconductor material may include multiple junctions. Additionally, in some aspects, variations of n(−−), n(−), n(+), n(++), p(−−), p(−), p(+), or p(++) type semiconductor layers can be used. The minus and positive signs are indicators of the relative magnitude of the doping of the semiconductor material.

The semiconductor materials of the present disclosure can also be made using a variety of manufacturing processes. In some cases the manufacturing procedures can affect the efficiency of the device, and may be taken into account in achieving a desired result. Exemplary manufacturing processes can include Czochralski (Cz) processes, magnetic Czochralski (mCz) processes, Float Zone (FZ) processes, epitaxial growth or deposition processes, and the like. Whether or not low oxygen content is desired in the device can also affect the choice of a manufacturing process for the semiconductor material. Various processes produce semiconductor materials containing varying amounts of oxygen, and as such, some applications having more stringent tolerances with respect to oxygen levels may benefit more from specific manufacturing procedures as compared to others. For example, during CZ crystal growth oxygen from the containment vessel, usually a quartz crucible, can become incorporated into the crystal as it is pulled. Additionally, other sources of oxygen contamination are also possible with the CZ process. Such contamination may be reduced, however, through the use of non oxygen-containing crucible materials, as well as the development of other crystal growth methods that do not utilize a crucible. One such process is the FZ process.

Materials grown with the CZ method can also be made to have lowered oxygen concentration through enhancements to the crystal growth process, such as growing the crystal in the presence of a magnetic field (i.e. the mCz process). Also, gettering techniques can be employed to reduce the impact of oxygen or other impurities on the finished device. These gettering techniques can include thermal cycles to liberate or nucleate impurities, or selective ion implantation of species to serve as gettering sites for the impurities. For example, oxygen concentrated in the semiconductor can be removed by the performing a furnace cycle to form a denuded zone. During heating with an inert gas, oxygen near the surface of the semiconductor diffuses out of the material. During the furnace cycle but after the denuding step, nucleating and growing steps may be performed. Nucleating sites for precipitates are formed during the nucleating step, and the precipitates are grown from the nucleating sites during a growing step. The precipitates are formed from interstitial oxygen within the bulk of the semiconductor material and beneath the denuded zone. The precipitation of oxygen in the bulk of the semiconductor material can be desired because such precipitates can act as gettering sites. Such precipitate formation can also be performed to “lock up” interstitial oxygen into the precipitates and reduce the likelihood that such oxygen can migrates from the bulk of the semiconductor material into the denuded zone.

In those aspects where low oxygen content of the device is desired, further processing of the semiconductor material can be performed so as to minimize the introduction of oxygen. Oxygen can exist in different states or at different sites (for example, interstitially or substitutionally) within a semiconductor such as silicon, dependent upon the thermal processing the semiconductor has received. If the semiconductor is subjected to temperatures higher than, for example, about 1000° C., oxygen can form aggregates or clusters that serve as defect sites in the crystal lattice. These sites may result in trap states and a reduction in carrier lifetime within the semiconductor material and device can occur. At lower temperatures (for example, around 400° C. to 700° C.), oxygen can behave as electrically active thermal donors. Thus, oxygen can have a negative impact on carrier lifetime and on carrier mobility. In a device fabricated to have photoconductive gain, the presence of oxygen causing reduced carrier lifetime may result in reduced levels of photoconductive gain.

It may be beneficial, therefore, to produce semiconductor materials such that a low oxygen content is obtained or maintained. This can be accomplished in a variety of ways, including using semiconductor materials having low levels of oxygen contained therein to begin with, processing these materials in a manner that minimizes the uptake of oxygen into the semiconductor lattice, and/or utilizing techniques that eliminate or reduce oxygen that may be present in the semiconductor. Such processes and techniques can include, for example, annealing the semiconductor material and any laser treated region to lower temperatures as compared to previous annealing procedures. Annealing processes are discussed more fully below.

Additionally, texture processing of the semiconductor material and/or any annealing process can be performed in a substantially oxygen-depleted environment in order to minimize the introduction of oxygen into the semiconductor. An oxygen-depleted or substantially oxygen-depleted environment can include a variety of environments. In one aspect, for example, the oxygen-depleted environment can be an environment whereby oxygen from the air or other sources has been replaced with a gas or other fluid containing little to no oxygen. In another aspect, processing can occur in a vacuum environment, and thus contain little to no oxygen. Additionally, oxygen-containing materials or materials that introduce oxygen into the semiconductor, such as, for example, quartz crucibles, can be avoided. As a practical matter, the term “oxygen-depleted environment” can be used to describe an environment with low levels of oxygen, provided a semiconductor material can be processed therein within the desired tolerances. Thus, environments having low oxygen, or little to no oxygen, are environments in which a semiconductor can be processed as a low-oxygen content semiconductor while maintaining oxygen levels within the tolerances of the present disclosure. In one aspect, an oxygen-depleted environment can be an oxygen-free environment. Further details regarding low-oxygen content semiconductor materials can be found in U.S. patent application Ser. No. 12/771,848, filed on Apr. 30, 2010, which is incorporated herein by reference.

The semiconductor material can have varying levels of interstitial oxygen depending on the desired efficiency of the device. In some aspects, oxygen content may be of no concern, and thus any level of oxygen within the material is acceptable. In other aspects, a low oxygen content is desired. In one aspect, a semiconductor material can have an oxygen content that is less than or equal to about 50 ppm atomic. In another aspect, a semiconductor material can have an oxygen content that is less than or equal to about 30 ppm atomic. In yet another aspect, the semiconductor material can have an oxygen content less than or equal to about 10 ppm atomic. In another aspect the semiconductor can have an oxygen content less than about 5 ppm atomic. In yet another aspect the semiconductor can have an oxygen content less than about 1 ppm atomic.

As has been described, the electromagnetic radiation absorption layer is comprised of a semiconductor material and an enhanced absorption region. The electromagnetic radiation absorption layer can be of various thicknesses, depending on the desired use of the material. In one aspect, for example, the electromagnetic radiation absorption layer has a thickness of from about 500 nm to about 100 μm. In another aspect, the electromagnetic radiation absorption layer has a thickness of from about 500 nm to about 15 μm. In yet another aspect, the electromagnetic radiation absorption layer has a thickness of from about 500 nm to about 5 μm. In a further aspect, the electromagnetic radiation absorption layer has a thickness of from about 500 nm to about 750 μm.

The enhanced absorption region can be associated with any portion of the semiconductor material, including both single and multiple sides, as well as being disposed within the semiconductor material. In one aspect the enhanced absorption region can be disposed on only a portion of one side of the semiconductor material as is shown in FIG. 1. In another aspect, as is shown in FIG. 2, the enhanced absorption region 14 can be disposed across and entire surface or across substantially the entire surface of the semiconductor material 12 as is shown in FIG. 2. In other aspects, the enhanced absorption region can be disposed across multiple surfaces or across portions of multiple surfaces of the semiconductor material (not shown). Additionally, in one aspect the enhanced absorption region can be formed or otherwise deposited on the semiconductor material. This can be accomplished by processing a portion of the semiconductor material into the enhanced absorption region, by the deposition of additional material, or both. In another aspect, the enhanced absorption region can be formed from the semiconductor material or a portion of the semiconductor material. In other words, the semiconductor material can be processed such that a portion of the semiconductor material is formed into the enhanced absorption region. This can be accomplished solely from the semiconductor material itself, or with the addition of other material. In yet another aspect, the enhanced absorption region can be formed within the semiconductor material.

As has been described, the electromagnetic radiation absorption layer including the enhanced absorption region can facilitate the enhanced absorption of electromagnetic radiation. In some aspects, the enhanced absorption region can be textured to include surface features that increase the effective absorption length of the photosensitive material. The surface features can be cones, pyramids, pillars, protrusions, microlenses, sphere-like structures, quantum dots, inverted features, and the like, including combinations thereof. Additionally, the surface features can have be micron-sized, nano-sized, or a combination thereof. For example, cones, pyramids, protrusions, and the like can have an average height within this range. In one aspect, the average height would be from the base of the feature to the distal tip of the feature. In another aspect, the average height would be from the surface plane upon which the feature was created to the distal tips of the feature. In one specific aspect, a feature (e.g. a cone) can have a height of from about 50 nm to about 2 μm. As another example, quantum dots, microlenses, and the like can have an average diameter within the micron-sized and/or nano-sized range. In addition to surface features, the enhanced absorption region can include an additional textured layer. In one aspect, for example, the enhanced absorption region can include a substantially conformal textured layer. Such a textured layer can have an average thickness of from about 1 nm to about 20 μm. In those aspects wherein the enhanced absorption region includes surface features, the conformal textured layer may have a varying thickness relative to the location on the surface features upon which is deposited. In the case of cones, for example, the conformal textured layer can become thinner toward the tips of the cones.

It is contemplated that the enhanced absorption region can be formed by various techniques, and any such method capable of producing a material having the properties according to aspects of the present disclosure should be included in the present scope. Nonlimiting examples of such techniques can include chemical etching (e.g. anisotropic etching, isotropic etching), mechanical texturing, laser treatment, nanoimprinting, material deposition, plasma etching, reactive ion etching, and the like, including combinations thereof.

In one specific aspect, the enhanced absorption region can be laser treated and thus be a laser enhanced absorption region. Laser treatment can be an effective technique for producing an enhanced absorption region across an entire surface or a portion of a surface of the semiconductor material. Thus in one aspect, laser treatment or processing allows discrete locations of the semiconductor material to be textured. A variety of techniques of laser processing to form a laser enhanced absorption region are contemplated, and any technique capable of forming such a region should be considered to be within the present scope. Laser treatment or processing can allow for, among other things, enhanced absorption properties and thus increased electromagnetic radiation focusing and detection. The laser treated region can be associated with the surface nearest the impinging electromagnetic radiation, or the laser treated surface can be associated with a surface opposite in relation to impinging electromagnetic radiation, thereby allowing the radiation to pass through the semiconductor material before it hits the laser treated region.

In one aspect, for example, a target region of the semiconductor material can be irradiated with laser radiation to form a laser enhanced absorption region. Examples of such processing have been described in further detail in U.S. Pat. Nos. 7,057,256, 7,354,792 and 7,442,629, which are incorporated herein by reference in their entireties. Briefly, a surface of a semiconductor material is irradiated with laser radiation to form a textured or surface modified region. Such laser processing can occur with or without a dopant material. In those aspects whereby a dopant is used, the laser can be directed through a dopant carrier and onto the semiconductor surface. In this way, dopant from the dopant carrier is introduced into the target region of the semiconductor material. Such a region incorporated into a semiconductor material can have various benefits in accordance with aspects of the present disclosure. For example, the target region typically has surface features and/or a textured layer that increases the surface area of the laser treated region, thereby increasing the probability of electromagnetic radiation absorption. In one aspect, such a target region is a substantially textured surface including micron-sized and/or nano-sized surface features that have been generated by the laser texturing. In another aspect, irradiating the surface of semiconductor material includes exposing the laser radiation to a dopant such that irradiation incorporates the dopant into the semiconductor. Various dopant materials are known in the art, and are discussed in more detail herein.

As such, the region of the semiconductor material is chemically and/or structurally altered by the laser treatment, which may, in some aspects, result in the formation of surface features appearing as microstructures, nanostructures, and/or patterned areas on the surface and, if a dopant is used, the incorporation of such dopants into the semiconductor material. In some aspects, the features can be on the order of 50 nm to 2 μm in size and can assist in the absorption of electromagnetic radiation. In other words, the textured surface can increase the probability of incident radiation being absorbed by the semiconductor material. In another aspect, the features can be on the order of 50 nm to 20 μm in size.

The type of laser radiation used to surface modify a semiconductor material can vary depending on the material and the intended modification. Any laser radiation known in the art can be used with the devices and methods of the present disclosure. There are a number of laser characteristics, however, that can affect the surface modification process and/or the resulting product including, but not limited to the wavelength of the laser radiation, beam size, beam shape, pulse width, pulse fluence, pulse frequency, polarization, laser propagation direction relative to the semiconductor material, degree of coherence, etc. In one aspect, a laser can be configured to provide pulsatile lasing of a semiconductor material. A short-pulsed laser is one capable of producing femtosecond, picosecond and/or nanosecond pulse durations. Laser pulses can have a central wavelength in a range of about from about 10 nm to about 8 μm, and more specifically from about 200 nm to about 1200 nm. The pulse width of the laser radiation can be in a range of from about tens of femtoseconds to about hundreds of nanoseconds. In one aspect, laser pulse widths can be in the range of from about 50 femtoseconds to about 50 picoseconds. In another aspect, laser pulse widths can be in the range of from about 50 picoseconds to 100 nanoseconds. In another aspect, laser pulse widths are in the range of from about 50 to 500 femtoseconds.

The number of laser pulses irradiating a target region can be in a range of from about 1 to about 2000. In one aspect, the number of laser pulses irradiating a semiconductor target region can be from about 2 to about 1000. Further, the repetition rate or frequency of the pulses can be selected to be in a range of from about 10 Hz to about 10 μtHz, or in a range of from about 1 kHz to about 1 MHz, or in a range from about 10 Hz to about 1 kHz. Moreover, the fluence of each laser pulse can be in a range of from about 1 kJ/m² to about 20 kJ/m², or in a range of from about 3 kJ/m² to about 8 kJ/m².

A variety of dopant materials are contemplated, and any such material that can be used in the laser treatment process to surface modify a region of the semiconductor material according to aspects of the present disclosure is considered to be within the present scope. It should be noted that the particular dopant utilized can vary depending on the semiconductor material being laser treated, as well as the intended use of the resulting semiconductor material. For example, the selection of potential dopants may differ depending on whether or not tuning of the photosensitive device is desired.

A dopant can be either electron donating or hole donating. In one aspect, non-limiting examples of dopant materials can include S, F, B, P, N, As, Se, Te, Ge, Ar, Ga, In, Sb, and combinations thereof. It should be noted that the scope of dopant materials should include, not only the dopant materials themselves, but also materials in forms that deliver such dopants (i.e. dopant carriers). For example, S dopant materials includes not only S, but also any material capable being used to dope S into the target region, such as, for example, H₂S, SF₆, SO₂, and the like, including combinations thereof. In one specific aspect, the dopant can be S. Sulfur can be present at an ion dosage level of from about 5×10¹⁴ to about 3×10²⁰ ions/cm². Non-limiting examples of fluorine-containing compounds can include ClF₃, PF₅, F₂SF₆, BF₃, GeF₄, WF₆, SiF₄, HF, CF₄, CHF₃, CH₂F₂, CH₃F, C₂F₆, C₂HF₅, C₃F₈, C₄F₈, NF₃, and the like, including combinations thereof. Non-limiting examples of boron-containing compounds can include B(CH₃)₃, BF₃, BCl₃, C₂B₁₀H₁₂, borosilica, B₂H₆, and the like, including combinations thereof. Non-limiting examples of phosphorous-containing compounds can include PF₅, PH₃, POCl₃, P₂O₅, and the like, including combinations thereof. Non-limiting examples of chlorine-containing compounds can include Cl₂, SiH₂Cl₂, HCl, SiCl₄, and the like, including combinations thereof. Dopants can also include arsenic-containing compounds such as AsH₃ and the like, as well as antimony-containing compounds. Additionally, dopant materials can include mixtures or combinations across dopant groups, i.e. a sulfur-containing compound mixed with a chlorine-containing compound. In one aspect, the dopant material can have a density that is greater than air. In one specific aspect, the dopant material can include Se, H₂S, SF₆, or mixtures thereof. In yet another specific aspect, the dopant can be SF₆ and can have a predetermined concentration range of about 5.0×10⁻⁸ mol/cm³ to about 5.0×10⁻⁴ mol/cm³. SF₆ gas is a good carrier for the incorporation of sulfur into the semiconductor material via a laser process without significant adverse effects on the semiconductor material. Additionally, it is noted that dopants can also be liquid solutions of n-type or p-type dopant materials dissolved in a solution such as water, alcohol, or an acid or basic solution. Dopants can also be solid materials applied as a powder or as a suspension dried onto the wafer.

The electromagnetic radiation absorbing layer can be annealed for a variety of reasons, including dopant activation, dopant diffusion, semiconductor material damage repair, and the like. In those aspects including a laser enhanced absorbing region, the semiconductor material can be annealed prior to laser treatment, following laser treatment, during laser treatment, or both prior to and following laser treatment. Annealing can enhance the semiconductive properties of the device, including increasing the photoresponse properties of the semiconductor materials. Additionally, annealing can reduce damage done by the lasing process. Although any known anneal can be beneficial and would be considered to be within the present scope, annealing at lower temperatures can be particularly useful. Such a “low temperature” anneal can greatly enhance the photoconductive gain and external quantum efficiency of devices utilizing such materials. In one aspect, for example, the semiconductor material can be annealed to a temperature of from about 300° C. to about 110° C.°. In another aspect, the semiconductor material can be annealed to a temperature of from about 500° C. to about 900° C. In yet another aspect, the semiconductor material can be annealed to a temperature of from about 700° C. to about 800° C. In a further aspect, the semiconductor material can be annealed to a temperature that is less than or equal to about 850° C.

The duration of the annealing procedure can vary according to the specific type of anneal being performed, as well as according to the materials being used. For example, rapid annealing processes can be used, and as such, the duration of the anneal may be shorter as compared to other techniques. Various rapid thermal anneal techniques are known, all of which should be considered to be within the present scope. In one aspect, the semiconductor material can be annealed by a rapid annealing process for a duration of greater than or equal to about 1 μs. In another aspect, the duration of the rapid annealing process can be from about 1 μs to about 1 ms. As another example, a baking or furnace anneal process can be used having durations that may be longer compared to a rapid anneal. In one aspect, for example, the semiconductor material can be annealed by a baking anneal process for a duration of greater than or equal to about 1 ms to several hours. As has been described, if low oxygen content semiconductor materials are used it may be beneficial to anneal such materials in a substantially oxygen-depleted environment.

As has been described, annealing can help reduce defects inherent to the semiconductor material and otherwise reduce electron/hole recombination. In other words, the annealing can help create electron states that effectively reduce the undesirable recombination processes. Annealing the semiconductor material may also improve the responsivity or photoconductive gain of the device. Photoconductive devices can have dopants, impurities, or defects that can introduce energy levels that can trap carriers. Trapping carriers and reducing recombination of photocarriers can lead to an increase in photoconductive gain of the device. The relationship of photoconductive gain and trapping time can be represented by Equation (V):

Gain=τ_{L}/τₜ (V)

where “τ_{L}” is the lifetime of an excess carrier and “τₜ” is the transit time of the carriers across the device. It is understood that the lifetime of an excess carrier can be increased by trapping a carrier species and reducing the recombination rate. An increase in gain can be achieved by trapping centers in the semiconductor that have millisecond trapping times at room temperature and short transit times in thinned lightly doped wafers. These trapping locations can decrease the recombination of carriers and therefore improve or increase the photoconductive gain of the device by allowing more electrons to traverse the different regions without being recombined.

In some aspects, a passivation layer can be disposed over at least portion of the semiconductor material and, in some cases, over at least a portion of the enhanced absorption region. The passivation layer can comprise various materials, non-limiting examples of which are, silicon dioxide (SiO₂), silicon nitride (Si₃N₄), amorphous silicon, and the like, including combinations thereof. The passivation layer can serve to confine electrical mobility within the device. In some cases, the passivation layer can be formed in situ from the semiconductor material during laser treatment. Furthermore, the passivation layer can also enhance the absorption or EQE of the device. In one aspect, for example, the passivation layer can increase the EQE of the device by at least 2% relative.

Additionally, in some aspects an optical layer may be disposed on the device to help trap photons in the device for absorption. In some cases the optical layer has a different refractive index than the semiconductor material. The optical layer can also be textured to enhance the absorption or trapping properties of the layer and/or device.

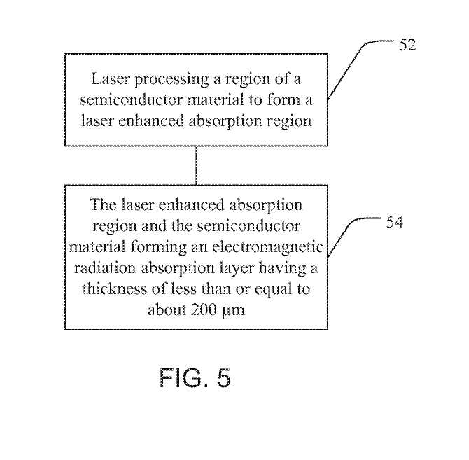

In another aspect of the present disclosure, a method of making a photosensitive semiconductor device is provided. As is shown in FIG. 5, such a method can include laser processing a region of a semiconductor material to form a laser enhanced absorption region 52, the laser enhanced absorption region and the semiconductor material forming an electromagnetic radiation absorption layer having a thickness of less than or equal to about 200 μm and operable to absorb greater than or equal to about 40% of incident electromagnetic radiation having at least one wavelength greater than or equal to about 1064 nm 54.

In yet another aspect of the present disclosure, a method of absorbing electromagnetic radiation is provided. Such a method can include applying electromagnetic radiation having at least one wavelength greater than or equal to about 1064 nm to an electromagnetic radiation absorption layer having a thickness of less than or equal to about 200 μm, wherein the electromagnetic radiation absorption layer includes a semiconductor material and an enhanced absorption region. The method also includes absorbing greater than or equal to about 40% of the electromagnetic radiation having at least one wavelength greater than or equal to about 1064 nm. In yet another aspect, the electromagnetic radiation absorption layer absorbs greater than or equal to about 40% of the electromagnetic radiation having at least one wavelength greater than or equal to about 1064 nm with an external quantum efficiency of greater than about 40%.

Of course, it is to be understood that the above-described arrangements are only illustrative of the application of the principles of the present disclosure. Numerous modifications and alternative arrangements may be devised by those skilled in the art without departing from the spirit and scope of the present disclosure and the appended claims are intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

1. A photosensitive imager device, comprising:
an electromagnetic radiation absorption layer having a thickness of less than or equal to about 200 μm, wherein the electromagnetic radiation absorption layer includes a semiconductor material and an enhanced absorption region.

2. The device of claim 1, wherein the electromagnetic radiation absorption layer is operable to absorb greater than or equal to about 40% of incident electromagnetic radiation having at least one wavelength greater than or equal to about 1060 nm.

3. The device of claim 1, wherein the electromagnetic radiation absorption layer has a thickness of less than or equal to about 20 μm.

4. The device of claim 3, wherein the electromagnetic radiation absorption layer is operable to absorb greater than or equal to about 40% of incident electromagnetic radiation having at least one wavelength greater than or equal to about 940 nm.

5. The device of claim 3, wherein the electromagnetic radiation absorption layer has an external quantum efficiency of at least about 40% at a wavelength of about 940 nm.

6. The device of claim 3, wherein the electromagnetic radiation absorption layer is operable to absorb greater than or equal to about 5% of incident electromagnetic radiation having at least one wavelength greater than or equal to about 1060 nm.

7. The device of claim 3, wherein the electromagnetic radiation absorption layer has an external quantum efficiency of at least about 5% at a wavelength of about 1060 nm.

8. The device of claim 1, wherein the electromagnetic radiation absorption layer has a thickness of less than or equal to about 5 μm.

9. The device of claim 8, wherein the electromagnetic radiation absorption layer is operable to absorb greater than or equal to about 15% of incident electromagnetic radiation having at least one wavelength greater than or equal to about 940 nm.

10. The device of claim 8, wherein the electromagnetic radiation absorption layer has an external quantum efficiency of at least about 15% at a wavelength of about 940 nm.

11. The device of claim 8, wherein the electromagnetic radiation absorption layer is operable to absorb greater than or equal to about 2% of incident electromagnetic radiation having at least one wavelength greater than or equal to about 1060 nm.

12. The device of claim 8, wherein the electromagnetic radiation absorption layer has an external quantum efficiency of at least about 2% at a wavelength of about 1060 nm.

13. The device of claim 1, wherein the semiconductor material includes a member selected from the group consisting of group IV materials, compounds and alloys comprising materials from groups II and VI, compounds and alloys comprising materials from groups III and V, and combinations thereof.

14. The device of claim 1, wherein the semiconductor material is silicon.

15. The device of claim 1, wherein the electromagnetic radiation absorption layer has an external quantum efficiency of at least about 40% at a wavelength of about 1060 nm.

16. The device of claim 1, wherein the electromagnetic radiation absorption layer has a thickness of from about 500 nm to about 100 μm.

17. The device of claim 1, wherein the electromagnetic radiation absorption layer has a thickness of from about 500 nm to about 15 μm.

18. The device of claim 1, wherein the electromagnetic radiation absorption layer has a thickness of from about 500 nm to about 5 μm.

19. The device of claim 1, wherein at least a portion of the semiconductor material is doped.

20. The device of claim 1, wherein the enhanced absorption region is a laser enhanced absorption region.

21-38. (canceled)
